(19) United States
(12) Patent Application Publication
(10) Pub. No.: US 2020/0337183 A1
(43) Pub. Date: Oct. 22, 2020

(54) SMARTPHONE VAPOR CHAMBER OF STAINLESS STEEL MATERIAL COATED WITH SIO2

(71) Applicant: POLAR&Co., INC., Gunpo-si (KR)

(72) Inventors: Kiwoo LEE, Daejeon (KR); Jongsun KIM, Hwaseong-si (KR); Sanggyung KIM, Suwon-si (KR); Jinglong CUI, Shenzhen city (CN)

(21) Appl. No.: 16/578,973

(22) Filed: Sep. 23, 2019

(30) Foreign Application Priority Data
Apr. 18, 2019 (KR) 10-2019-0045291

(51) Int. Cl. H05K 7/20; F28D 15/04

(52) U.S. Cl. CPC H05K 7/20336; H01L 23/427; F28D 15/046

(57) ABSTRACT

Provided is a smartphone vapor chamber of a stainless steel material coated with SiO₂. The smartphone vapor chamber is configured such that strength of the existing smartphone vapor chamber, which employs a copper material, is increased by employing a stainless steel material, movement of a working fluid is facilitated by forming a wick groove in the smartphone vapor chamber, all surfaces or any one surface of upper and lower plates forming the smartphone vapor chamber is coated with SiO₂. Owing to the SiO₂ coating, a circulation of the working fluid is accelerated by improving heat transfer, an infiltration rate, and a capillary force, heat radiation is maximized, and the smartphone vapor chamber has effects of having thermal resistance and operation performance which are similar to those of a vapor chamber using copper and of not affecting a variation in thickness of a frame.

### BACKGROUND

### 1. Field of the Invention

The present invention relates to a smartphone vapor chamber of a stainless steel material coated with SiO₂, in which stainless steel is employed as a material of a vapor chamber which serves as a cooling device for cooling a semiconductor in a smartphone, and a surface of the stainless steel is coated with SiO₂ having high thermal conductivity so as to improve a heat transfer effect of the stainless steel.

### 2. Discussion of Related Art

Describing basic structures of smartphones, current smartphones have a structure in which a frame structure made of stainless steel, magnesium, or aluminum is provided inside the smartphone, a display is mounted at a front side of the frame, and a driving circuit and a battery are mounted at a rear side of the frame.

In the smartphones, since a processing speed of a central processing unit (CPU) is fast and the CPU performs various operations, an operation amount of the CPU is increased, and thus, heat generated in the CPU is increased. Moreover, due to a slim structure of the smartphones, it is not easy to install an effective cooling unit in the smartphones.

Therefore, high heat is generated in the smartphones, and excessive heat generated in the smartphones causes discomfort and anxiety to a user. That is, since it has been reported that the smartphones have been exploded due to battery failure, or the like, when the smartphones become too hot, a user may be in great anxiety. Aside from the explosion, heat generated in the smartphones may damage semiconductors inside the smartphones or cause operation errors, and thus, it is necessary to radiate heat and cool the heat as quickly as possible. A material of a heat radiation vapor chamber of all smartphones and mobile products, which are currently available in the market, is pure copper. The reason is that, since thermal conductivity of copper is very high (400 w/mk), a material having better thermal conductivity is more advantageous to a thin film vapor chamber. Therefore, a stainless steel material with low thermal conductivity (12 to 45 w/mk) is not used and a vapor chamber employing the stainless steel material is not available in the market at present. However, as the vapor chamber made of a copper material is employed, there are problems in that an inner thickness of the vapor chamber becomes as much as 0.5 mm thicker, the vapor chamber is easily damaged by a slight impact or contact due to softness of the copper material, and both surfaces of the vapor chamber are adhered to an inner frame of a smartphone such that thermal resistance is generated to degrade radiation of heat. Therefore, as a cooling device for a smartphone, a smartphone vapor chamber in which a stainless steel material is usable and which can solve the above problems is being manufactured and developed.

### SUMMARY OF THE INVENTION

The present invention is directed to a stainless steel plate type smartphone vapor chamber which is capable of achieving operating performance, which is substantially the same as that of pure copper, using a stainless steel material having high strength, wherein thermal resistance of the existing stainless steel vapor chamber, which is not coated and is employed in a smartphone, i.e., a ratio (ΔT/Q) of a temperature difference (ΔT=Th−T2) between a temperature Th of a contact point of a heat source and a temperature T2 of a position of a cooling part to a heating amount Q, is 3.1 C/W which is greater than thermal resistance of about 1.0 C/W of a vapor chamber in which copper is employed.

Accordingly, in order to reduce thermal resistance in a vapor chamber of a qstainless steel material, the present invention is directed to a smartphone vapor chamber of a stainless steel material using SiO₂ coating in which a SiO₂ coating technique is applied to an interior of a stainless steel plate type vapor chamber, wherein, as a SiO₂ material having excellent water absorptivity is used, a heat transfer effect of a coated surface is improved so that thermal resistance of the vapor chamber of the stainless steel material coated with the SiO₂ material, i.e., a ratio (ΔT/Q) of a temperature difference (ΔT=Th−T2) between a temperature Th of a contact point of a heat source and a temperature T2 of a position of a cooling part to a heating amount Q, becomes 1.25 C/W such that the thermal resistance is substantially the same as that of pure copper.

Other objects and advantages of the present invention will be described below and will be understood by embodiments of the present invention. Further, the objects and advantages of the present invention can be implemented by means and a combination thereof which are described in the appended claims.

According to an aspect of the present invention, there is provided a smartphone vapor chamber of a stainless steel material coated with SiO₂, which includes a smartphone vapor chamber (20) made of a stainless steel material in a plate type such that, among upper and lower plates (21) and (22) which are correspondingly adhered to each other to form the smartphone vapor chamber (20) so as to form an accommodation space (24) of a working fluid, one surface of the upper plate (21) in the accommodation space (24), in which a wick groove (27) for movement of the working fluid is formed, is coated with SiO₂ to increase an infiltration rate and a capillary force of the working fluid in the accommodation space (24), thereby increasing a circulation speed and reducing movement friction of vapor of the working fluid, being configured to maintain a temperature difference between one side portion (T1) in contact with a heater (40) and the other side portion (T2) facing the one side portion (T1) within a predetermined temperature range to increase a heat radiation effect, and having increased strength when coupled to a smartphone frame (10).

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a conceptual diagram illustrating SiO₂ coating of a smartphone vapor chamber according to one embodiment of the present invention;

FIG. 2 shows diagrams illustrating whether the smartphone vapor chamber is coated according to one embodiment of the present invention;

FIG. 3 shows photographs representing a comparative test between capillary forces of two plates of FIG. 2;

FIG. 4 shows comparative test data representing a comparison in temperature difference between upper and lower sides of the plate of FIG. 2;

FIG. 5 is a photograph showing a test in temperature difference between the upper and lower sides of the plate of FIG. 4, which are coated with SiO₂, of the smartphone vapor chamber (plate) of the present invention;

FIG. 6 is a photograph showing a test in temperature difference between the upper and lower sides of the plate of FIG. 4, which are not coated with SiO₂;

FIG. 7 is a diagram illustrating a smartphone vapor chamber of a stainless steel material using SiO₂ coating according to one embodiment of the present invention;

FIG. 8 is a diagram illustrating a process of integrally manufacturing a smartphone frame with the smartphone vapor chamber of a stainless steel material using SiO₂ coating according to one embodiment of the present invention; and

FIG. 9 is a diagram illustrating various embodiments for manufacturing a smartphone vapor chamber of a stainless steel material using SiO₂ coating according to the present invention.

### DETAILED DESCRIPTION OF EXEMPLARY EMBODIMENTS

Before describing various embodiments of the present inventive concept in detail, it is to be understood that the present inventive concept is not limited in its application to the details of configurations and arrangements of components set forth in the following detailed description or drawings. The present inventive concept is capable of being implemented in other embodiments and of being practiced and carried out in various ways. Also, it is to be understood that phraseology and terminology used herein with reference to device or element orientation (such as, for example, terms like “front,” “back,” “up,”, “down,” “top,” “bottom,” “left,” “right,” “lateral,” and the like) are only used to simplify description of the present inventive concept, and do not alone indicate or imply that the device or element referred to must have a particular orientation. In addition, terms such as “first” and “second” are used in the present specification and the appended claims for the purpose of description and are not intended to indicate or imply relative importance or purpose.

The present inventive concept has the following features in order to achieve the above object.

Hereinafter, exemplary embodiments of the present inventive concept will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present inventive concept on the basis of the principle that the inventor is allowed to define terms appropriately for the best explanation.

Therefore, the embodiments disclosed in the present specification and the configurations illustrated in the drawings are merely the most exemplary embodiments of the present inventive concept, and do not represent all of the technical ideas of the present inventive concept, and thus it should be understood that there may be various equivalents and modified examples that could substitute therefor at the time of filing the present application.

To describe one embodiment of the present invention, a smartphone vapor chamber 20 is made of a stainless steel material in a plate type such that, among upper and lower plates 21 and 22 which are correspondingly adhered to each other to form the smartphone vapor chamber 20 so as to form an accommodation space 24 of a working fluid, one surface of the upper plate 21 in the accommodation space 24, in which a wick groove 27 for movement of the working fluid is formed, is coated with SiO₂ to increase an infiltration rate and a capillary force of the working fluid in the accommodation space 24, thereby increasing a circulation speed and reducing movement friction of vapor of the working fluid, being configured to maintain a temperature difference between one side portion T1 in contact with a heater 40 and the other side portion T2 facing the one side portion T1 within a predetermined temperature range to increase a heat radiation effect, and having increased strength when coupled to a smartphone frame 10.

Further, one surface of the lower plate 22, in which the wick groove 27 in the accommodation space 24 is formed, is coated with SiO₂.

Further, the SiO₂ coating process is performed such that a plurality of plates are fixedly attached to a bottom surface of a seating base 31 in a SiO₂ coating chamber 30 which is maintained in a predetermined temperature range and a vacuum state, SiO₂ vapor, which is generated while SiO₂ heated by a heat source 34 is melted below the smartphone vapor chamber 20, attaches to surfaces of the plates so that the plates are coated with SiO₂, wherein, during the SiO₂ coating process, the seating base 31 is rotated at a preset speed so that the SiO₂ vapor may be uniformly distributed and coated on surfaces of the plates.

Further, the smartphone vapor chamber 20 is separately correspondingly adhered to one surface of the smartphone frame 10.

Further, the smartphone vapor chamber 20 is correspondingly inserted into and mounted on a mounting part 12, which is formed on the smartphone frame 10, with the same thickness and is coplanar with the smartphone frame 10 so as to not affect a thickness variation.

Further, when upper and lower plates 14 and 16 forming the smartphone frame 10 are correspondingly coupled, the accommodation space 24 formed on corresponding surfaces of the upper and lower plates 14 and 16 is used as the smartphone vapor chamber 20 such that a thickness variation of the smartphone frame 10 is not affected.

Further, the SiO₂ coating process is applicable to a coating process for internal components of portable electronic devices.

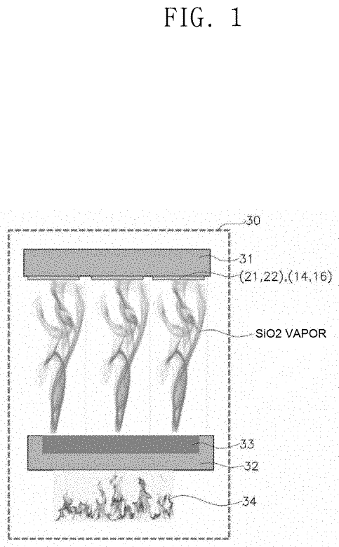

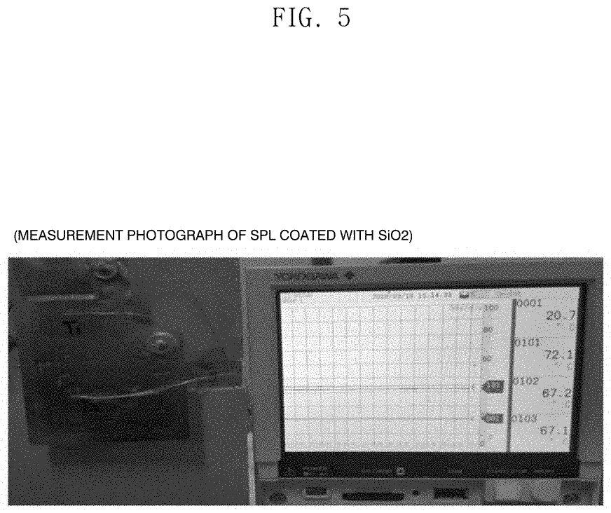

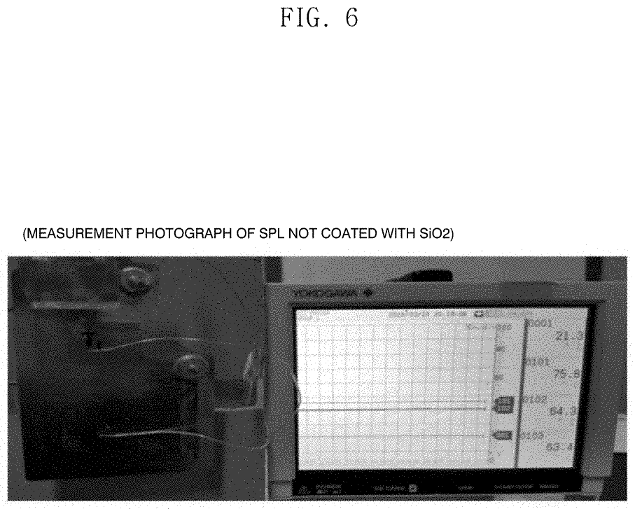

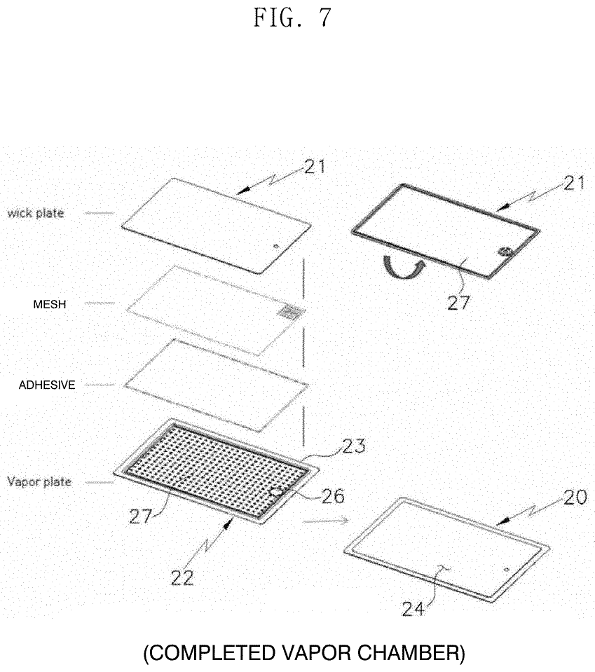

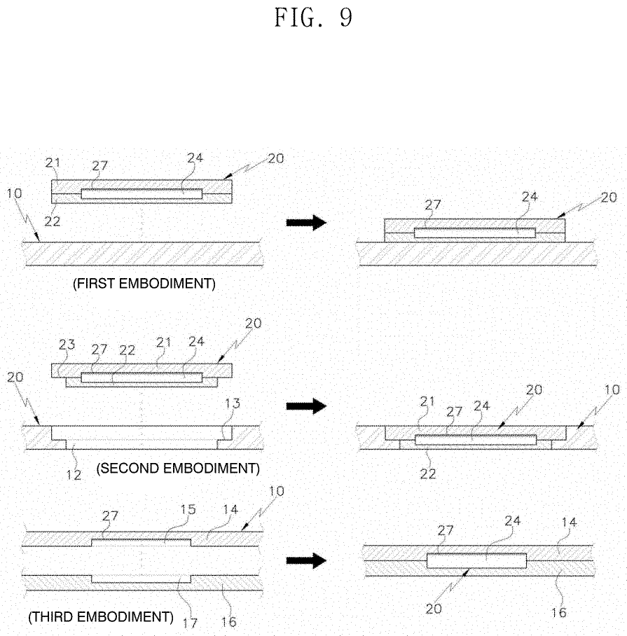

Hereinafter, a smartphone vapor chamber using SiO₂ coating according to exemplary embodiments of the present invention will be described in detail with reference to FIGS. 1 to 9.

In the smartphone vapor chamber of a stainless steel material coated with SiO₂ according to the present invention, the upper and lower plates 21 and 22 are adhered to each other by a method among various methods which are set by an operator so that the empty accommodation space 24 in which a working fluid moves is formed. The wick groove 27 (wherein a wick (which is provided in the form of a groove or a protrusion toward a movement direction of the working fluid to serve to increase a movement speed of the working fluid) is formed or a mesh serving as the wick is seated on a groove) is formed on a corresponding surface of each of the upper and lower plates 21 and 22 forming the accommodation space 24 or is formed on one surface of the upper and lower plates 21 and 22 in the accommodation space 24 such that movement of the working fluid is facilitated.

According to the present invention, all corresponding surfaces of the upper and lower plates 21 and 22 are coated with SiO₂. However, for convenience of description, only a bottom surface of the upper plate 21 on which the wick groove 27 is formed is coated with SiO₂.

In the present invention, one surface of the upper plate 21 on which the wick groove 27 is formed is coated with SiO₂ to increase an infiltration rate and a capillary force of an internal working fluid, thereby increasing a circulation speed of the internal working fluid and reducing movement friction thereof. In addition, a temperature difference between the one side portion T1 in contact with the heater 40 and the other side portion T2 facing the one side portion T1 is maintained within a predetermined temperature range (e.g., 5° C.) such that a heat radiation effect is increased.

Further, the upper and lower plates 21 and 22 of the smartphone vapor chamber 20 manufactured according to the present invention have thermal conductivity which is the same as that of a conventional copper material. Even when the upper and lower plates 21 and 22 are manufactured integrally with the smartphone frame 10, the upper and lower plates 21 and 22 are each formed of a stainless steel in a plate type while strength is increased and a thickness variation of the smartphone frame 10 is not affected.

A method of coating SiO₂ will be described below with reference to FIG. 1.

1. The seating base 31 is installed on an inner upper end of the SiO₂ coating chamber 30, a plurality of plates (which are coating targets and correspond to all of the upper and lower plates 21 and 22 or any one of the upper and lower plates 21 and 22 (in the present invention, the upper plate 21 corresponding to a wick plate becomes a coating target. In particular, in the upper plate 21, a bottom surface on which a wick groove is formed to allow a mesh to be mounted is coated)) which form the smartphone vapor chamber 20 are spaced to be fixedly adhered to the bottom surface of the seating base 31, and a SiO₂ material 33 is put into a SiO₂ seating base 32 installed to be spaced at a predetermined distance apart from a lower end of the seating base 31.

2. In order to make an interior of the SiO₂ coating chamber 30 into a vacuum, a temperature of the interior of the SiO₂ coating chamber 30 is increased to a preset temperature.

3. The interior of the SiO₂ coating chamber 30 is vacuumed.

4. The temperature of the interior of the SiO₂ coating chamber 30 is set to a preset temperature at which a SiO₂ vapor is deposited well.

5. The SiO₂ seating base 32 is heated using various heat sources 34 (heating parts) to a temperature of 1400° C. or more to melt the SiO₂ material 33.

6. The SiO₂ vapor, which is generated as the SiO₂ material 33 is melted, moves upward to one surface of a coating target which is attached to the seating base 31.

7. The SiO₂ vapor, which moves upward, is deposited on the surface of the coating target such that the coating target is coated with SiO₂. In this case, the seating base 31 is rotated at a predetermined speed at a preset position during the SiO₂ coating process (a rotation direction is changed at predetermined time intervals) such that the SiO₂ vapor may be uniformly distributed on the surface of the coating target and thus the coating target may be coated with SiO₂.

8. The coating target is taken out of the SiO₂ coating chamber 30.

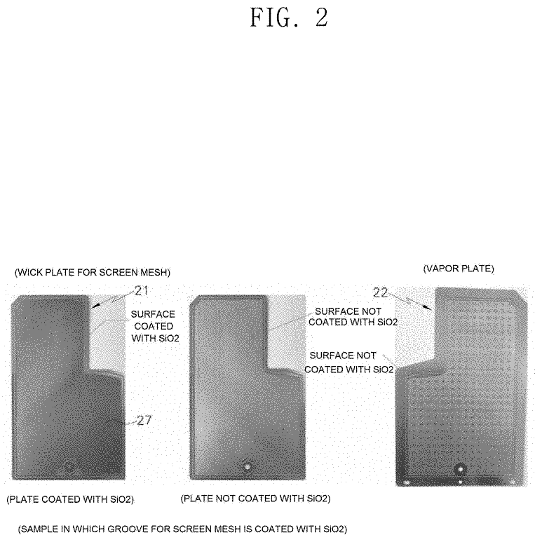

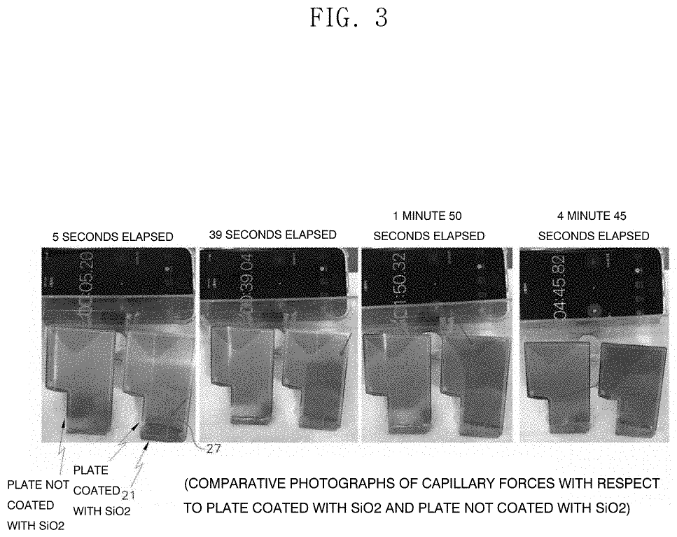

In FIG. 2, it can be confirmed that the upper plate 21 is coated with SiO₂ by the above-described method. FIG. 3 shows a comparison of capillary forces between the upper plate 21 coated with SiO₂ and a plate not coated with SiO₂. A bottom of the upper plate 21, which was coated with SiO₂ and positioned on the right side among the two plates, was entirely filled with water due to a strong capillary force in about 4 minutes and 50 seconds. However, it can be seen that no capillary force was generated in the plate positioned on the left side which was not coated with SiO₂.

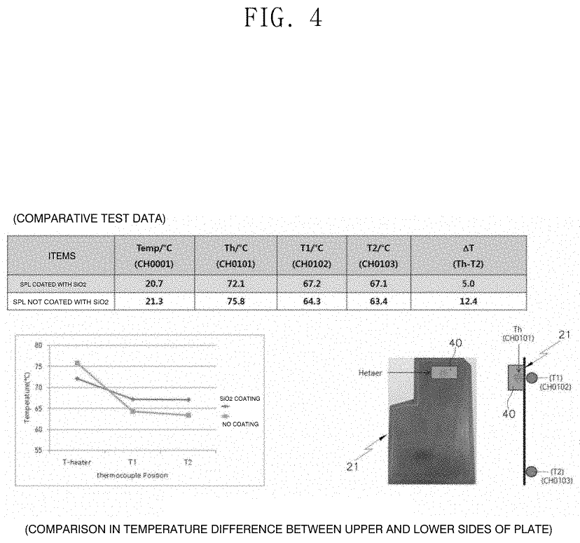

FIGS. 4 to 6 show comparative test data of a temperature difference between one side portion CH0102(T1) in contact with the heat source 34 (CH0101(TH)) and the other side portion CH0103(T2) which is furthest away from the heat source 34 (CH0101(TH)) with respect to the upper plate 21 coated with SiO₂ and the plate not coated with SiO₂. It can be seen that, in the case that SiO₂ is not coated, a temperature difference of 12° C. was exhibited, whereas, in the case that SiO₂ is coated, a temperature difference of 5° C. was exhibited. Consequently, it can be seen that a heat radiation effect is also excellent over the upper plate 21.

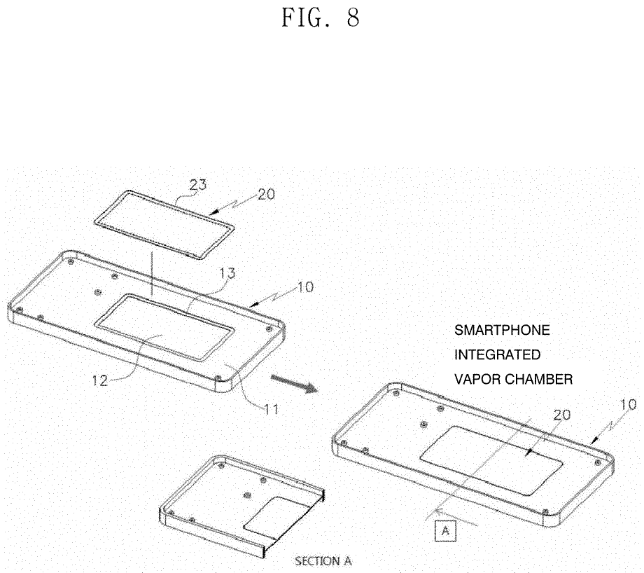

Further, the smartphone vapor chamber 20 of a stainless steel material coated with SiO₂, which are manufactured as described above, may be integrally manufactured with the smartphone frame 10. As shown in FIG. 8, in the present invention, three embodiments are proposed.

The three embodiments includes a first embodiment in which the smartphone vapor chamber 20 is correspondingly attached to one surface of the smartphone frame 10, a second embodiment in which the smartphone vapor chamber 20 is correspondingly inserted into and mounted on a mounting portion, which is formed on the smartphone frame 10, so as to not affect a variation in thickness of the smartphone frame 10, and a third embodiment in which, when the upper and lower plates 14 and 16 forming the smartphone frame 10 are correspondingly coupled, the accommodation space 24 formed on corresponding surfaces of the upper and lower plates 14 and 16 is used as the smartphone vapor chamber 20 such that a variation in thickness of the smartphone frame 10 is not affected.

1. The first embodiment proposes a general adhesion form in which the smartphone vapor chamber 20 of the present invention is correspondingly adhered and fixed to one surface of the smartphone frame 10.

2. The second embodiment is configured such that, when the smartphone vapor chamber 20 is integrally manufactured with the smartphone frame 10, a thickness of the smartphone frame 10 is not affected. The second embodiment includes the smartphone frame 10 in which a mounting part 12 is formed to vertically penetrate a base 11 and a first bump 13 is formed on an edge of one surface of the mounting part 12, and the smartphone integrated vapor chamber 20 in which the upper and lower plates 21 and 22 are adhered to form the accommodation space 24 for a working fluid in the smartphone integrated vapor chamber 20, and a second bump 23 is correspondingly mounted on the mounting part 12 of the smartphone frame 10 and is formed to correspond to the first bump 13 on an edge of one surface of the smartphone integrated vapor chamber 20 so as to not protrude the upper and lower plates 21 and 22 to the upper and lower surface of the base 11 and in order for the vapor chambers 20 to be coplanar with each other.

More specifically, the second embodiment is a case in which a separate smartphone integrated vapor chamber 20 is mounted on the smartphone frame 10.

The smartphone frame 10 is configured such that the mounting part 12 is formed to vertically penetrate the base 11 of the smartphone frame 10 at a position which is predetermined by a user, and the first bump 13 is formed to be recessed on the edge of one surface of the mounting part 12 (which is a surface on which the smartphone integrated vapor chamber 20, which will be described below, will be correspondingly mounted).

The smartphone integrated vapor chamber 20 is configured such that the upper and lower plates 21 and 22 (where the upper plate 21 is a vapor plate (made of a stainless steel (SUS) material) and the lower plate 22 is a wick plate (made of a SUS material)) are vertically integrally adhered. The smartphone integrated vapor chamber 20 is correspondingly adhered to the mounting part 12 of the above-described smartphone frame 10 with a predetermined adhesive means (any one selected from among a double-sided tape adhesion method, a soldering method, a brazing method, a bonding method, or two selected from thereamong). When the smartphone integrated vapor chamber 20 is mounted on the smartphone frame 10, the smartphone integrated vapor chamber 20 is coupled to the smartphone frame 10 to be coplanar with the base 11 of the smartphone frame 10 so as to prevent the smartphone frame 10 from becoming thicker due to a further protrusion of a thickness of the base 11.

To this end, the second bump 23 corresponding to the first bump 13 is formed on the edge of one surface of the smartphone integrated vapor chamber 20, which corresponds to the above-described mounting part 12, so that the smartphone integrated vapor chamber 20 is coupled to the smartphone frame 10. The accommodation space 24 for a working fluid is formed in the smartphone integrated vapor chamber 20 so that the working fluid in the accommodation space 24 is heated and vaporized to move upward in one side in the accommodation space 24 by the heater 40 which is positioned outside the smartphone integrated vapor chamber 20 (various heaters 40 in the smartphone frame 10 (positions including a main control board, a battery, and the like at which heat is generated by being in close contact with one side of one surface of the smartphone integrated vapor chamber 20), and the vaporized working fluid is condensed to fall while moving in a length direction and repeats circulation moving toward a space side of the heater 40.

Further, protrusions (not shown) or holes (not shown) may be formed on the first and second bumps 13 and 23 so that the first bump 13 corresponds and is coupled to the second bump 23 to increase engagement force between the first bump 13 and the second bump 23. When a plurality of protrusions are formed to be spaced and to protrude from the first bump 13, a plurality of holes are formed to be spaced and to penetrate into the second bump 23, thereby corresponding to the plurality of protrusions.

Alternatively, both of holes and protrusions may be alternately formed on the first bump 13 and the second bump 23 (this is also applicable to the third embodiment which will be described below).

Further, a brazing adhesive is inserted around an edge of the accommodation space 24 and then the smartphone integrated vapor chamber 20 is assembled with the accommodation space 24 by performing a brazing process in a vacuum brazing furnace at a preset temperature. After the brazing process, the accommodation space 24 is filled with the working fluid and vacuumed and then an inlet 26 for the working fluid is directly manufactured by welding without a separate injection line for injecting a working fluid.

3. As in the second embodiment, the third embodiment is configured such that, when a smartphone integrated vapor chamber 20 is integrally manufactured with a smartphone frame 10, the thickness of the smartphone frame 10 is not affected. The third embodiment includes the smartphone frame 10 which includes an upper plate 14 having one surface on which a first accommodation part 15 is formed to be recessed and a lower plate 16 in which a second accommodation part 17 corresponding to the first accommodation part 15 is formed to be recessed, and a smartphone integrated vapor chamber 20 in which the upper and lower plates 14 and 16 are coupled through a predetermined adhesive means and an accommodation space 24 of a working fluid is formed between the upper and lower plates 14 and 16 by the first accommodation part 15 and the second accommodation part 17, and which is integrated with the smartphone frame 10.

More specifically, in the third embodiment, the upper plate 14 and the lower plate 16 integrally form the smartphone frame 10. The smartphone frame 10 is configured such that the upper plate 14, in which the first accommodation part 15 is formed to be recessed on one surface of the smartphone frame 10, is coupled to the lower plate 16, in which the second accommodation part 17 corresponding to the first accommodation part 15 is formed to be recessed, through a predetermined adhesive means. That is, the smartphone integrated vapor chamber 20 is formed in the smartphone frame 10 by the first and second accommodation parts 15 and 17 as a portion forming the accommodation space 24 of the working fluid.

In the first and second embodiments, since the upper and lower plates 21 and 22 are used to form the smartphone vapor chamber 20, one surface of each of the upper and lower plates 21 and 22 or any one surface of the upper and lower plates 21 and 22 (which forms the accommodation space 24) is coated with SiO₂ in the SiO₂ coating chamber 30. However, in the third embodiment, since the smartphone frame 10 forms the smartphone vapor chamber 20, it is obvious that the upper and lower plates 14 and 16 forming the smartphone frame 10 are coated with SiO₂ in the SiO₂ coating chamber 30.

Further, it will be appreciated that the above-described SiO₂ coating process of the present invention is applicable to coating of internal components of various portable electronic devices, such as a laptop computer, a tablet personal computer (PC), a wireless charger, a portable game machine, and the like, according to various embodiments of a user.

As described above, in accordance with the present invention, a stainless steel material is employed such that there is an effect of increasing strength of a smartphone frame.

Further, when the stainless steel material is applied to a smartphone, it can be manufactured integrally with a frame, and even when a vapor chamber is applied to the frame, there is no change in thickness, and therefore, there is an effect in that the stainless steel material is highly competitive in thickness-sensitive smartphone.

Further, the stainless steel material can be used in other mobile products such that there is an effect in that the stainless steel material is integrated with a frame.

Further, a material cost of the stainless steel material is considerably lower than that of pure copper, generation of defects in the stainless steel material due to rust or damage is significantly lower than that of the pure copper, and a heat radiation effect is also excellent such that there is an effect in that the stainless steel material is advantageous in the 5G era.

Further, when a vapor chamber of pure copper is applied to a smartphone, there is a disadvantage in that the pure copper is quite soft and an overall thickness of the smartphone is increased by as much as at least 0.5 mm.

However, in accordance with the present invention, these problems do not occur such that there is an effect of having a significant advantage in the smartphone market.

As described above, although the present invention has been described by way of a specific embodiment and the accompanying drawings, it is not limited thereto, and it should be understood that numerous other changes and modifications can be devised by those skilled in the art that will fall within the spirit and scope of the present invention and along with the full range of equivalents to which the appended claims are entitled.

What is claimed is:

1. A smartphone vapor chamber of a stainless steel material coated with SiO₂, comprising:
a smartphone vapor chamber (20) made of a stainless steel material in a plate type such that, among upper and lower plates (21) and (22) which are correspondingly adhered to each other to form the smartphone vapor chamber (20), one surface of the upper plate (21) in the accommodation space (24), in which a wick groove (27) for movement of the working fluid is formed, is coated with SiO₂ to increase an infiltration rate and a capillary force of the working fluid in the accommodation space (24), thereby increasing a circulation speed and reducing movement friction of vapor of the working fluid, being configured to maintain a temperature difference between one side portion (T1) in contact with a heater (40) and the other side portion (T2) facing the one side portion (T1) within a predetermined temperature range to increase a heat radiation effect, and having increased strength when coupled to a smartphone frame (10).

2. The smartphone vapor chamber of claim 1, wherein the SiO₂ coating process is further applied to one surface of the lower plate (22) in which the wick groove (27) is formed in the accommodation space (24).

3. The smartphone vapor chamber of claim 1, wherein the SiO₂ coating process is performed such that, in a SiO₂ coating chamber (30) which is maintained in a predetermined temperature range and in a vacuum state, a plurality of plates are fixedly attached to a bottom surface of a seating base (31) and then a SiO₂ vapor, which is generated as a SiO₂ material is heated by a heat source (34) and melted below the smartphone vapor chamber (20), adheres to a surface of the plate such that the plate is coated with SiO₂,
wherein, during the SiO₂ coating process, the seating base (31) is rotated at a preset speed such that the SiO₂ vapor is uniformly distributed on the surface of the plate and the plate is coated with SiO₂.

4. The smartphone vapor chamber of claim 1, wherein the smartphone vapor chamber (20) is separately adhered to one surface of the smartphone frame (10).

5. The smartphone vapor chamber of claim 1, wherein the smartphone vapor chamber (20) is correspondingly inserted into and mounted on a mounting part (12) formed on the smartphone frame (10) with the same thickness to have a surface, in which a thickness variation does not occur, that is coplanar with the smartphone frame (10).

6. The smartphone vapor chamber of claim 1, wherein, when upper and lower plates (14) and (16) forming the smartphone frame (10) are correspondingly coupled, the accommodation space (24) formed on corresponding surfaces of the upper and lower plates (14) and (16) is used as the smartphone vapor chamber (20).

7. The smartphone vapor chamber of claim 1, wherein the SiO₂ coating process is applicable to a portable electronic device.

8. The smartphone vapor chamber of claim 2, wherein the SiO₂ coating process is performed such that, in a SiO₂ coating chamber (30) which is maintained in a predetermined temperature range and in a vacuum state, a plurality of plates are fixedly attached to a bottom surface of a seating base (31) and then a SiO₂ vapor, which is generated as a SiO₂ material is heated by a heat source (34) and melted below the smartphone vapor chamber (20), adheres to a surface of the plate such that the plate is coated with SiO₂,
wherein, during the SiO₂ coating process, the seating base (31) is rotated at a preset speed such that the SiO₂ vapor is uniformly distributed on the surface of the plate and the plate is coated with SiO₂.

9. The smartphone vapor chamber of claim 2, wherein the smartphone vapor chamber (20) is separately adhered to one surface of the smartphone frame (10).

10. The smartphone vapor chamber of claim 2, wherein the smartphone vapor chamber (20) is correspondingly inserted into and mounted on a mounting part (12) formed on the smartphone frame (10) with the same thickness to have a surface, in which a thickness variation does not occur, that is coplanar with the smartphone frame (10).

11. The smartphone vapor chamber of claim 2, wherein, when upper and lower plates (14) and (16) forming the smartphone frame (10) are correspondingly coupled, the accommodation space (24) formed on corresponding surfaces of the upper and lower plates (14) and (16) is used as the smartphone vapor chamber (20).

12. The smartphone vapor chamber of claim 2, wherein the SiO₂ coating process is applicable to a portable electronic device.
